(19) United States
(12) Patent Application Publication
(10) Pub. No.: US 2014/0307374 A1
(43) Pub. Date: Oct. 16, 2014

(54) SWIVELLING COVER ON REAR WALL OF ELECTRONIC DEVICE CHASSIS

(71) Applicants: Hong Fu Jin Precision Industry (ShenZhen) Co., LTD., (US); HON HAI PRECISION INDUSTRY CO., LTD., New Taipei (TW)

(72) Inventors: LEI LIU, Shenzhen (CN); GUO-YI CHEN, Shenzhen (CN)

(73) Assignees: HON HAI PRECISION INDUSTRY CO., LTD., New Taipei (TW); HONG FU JIN PRECISION INDUSTRY (SheZhen) CO., LTD., Shenzhen (CN)

(21) Appl. No.: 13/873,129

(22) Filed: Apr. 29, 2013

(30) Foreign Application Priority Data
Apr. 16, 2013 (CN) 2013101312148

(51) Int. Cl. H05K 5/03

(52) U.S. Cl. CPC H05K 5/03
USPC 361/679.02

(57) ABSTRACT

A electronic device rear wall includes a wall body defining a slot to accommodate a connector of an expansion card; and a swiveling cover pivotably mounted to the wall body, to cover the slot when not in use, or uncover the slot when required.

### BACKGROUND

1. Technical Field

The present disclosure relates to a rear wall of an electronic device chassis.

2. Description of Related Art

A rear wall of an electronic device chassis, such as a computer rear wall, defines a plurality of expansion slots to accommodate connectors of expansion cards. When expansion cards are not installed to the chassis, the expansion slots are covered by covering pieces which are mounted to the rear wall by screws. As a result, it is time consuming to install or uninstall the covering pieces. Furthermore, the covering pieces are easily lost if uninstalled from the rear wall.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a rear wall of an electronic device chassis.

FIG. 2 is an enlarged view of the circled portion II of FIG. 1.

FIG. 3 is an enlarged view of the circled portion III of FIG. 1.

FIG. 4 is an assembled view of FIG. 1.

FIG. 5 is similar to FIG. 4, but showing another using state.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

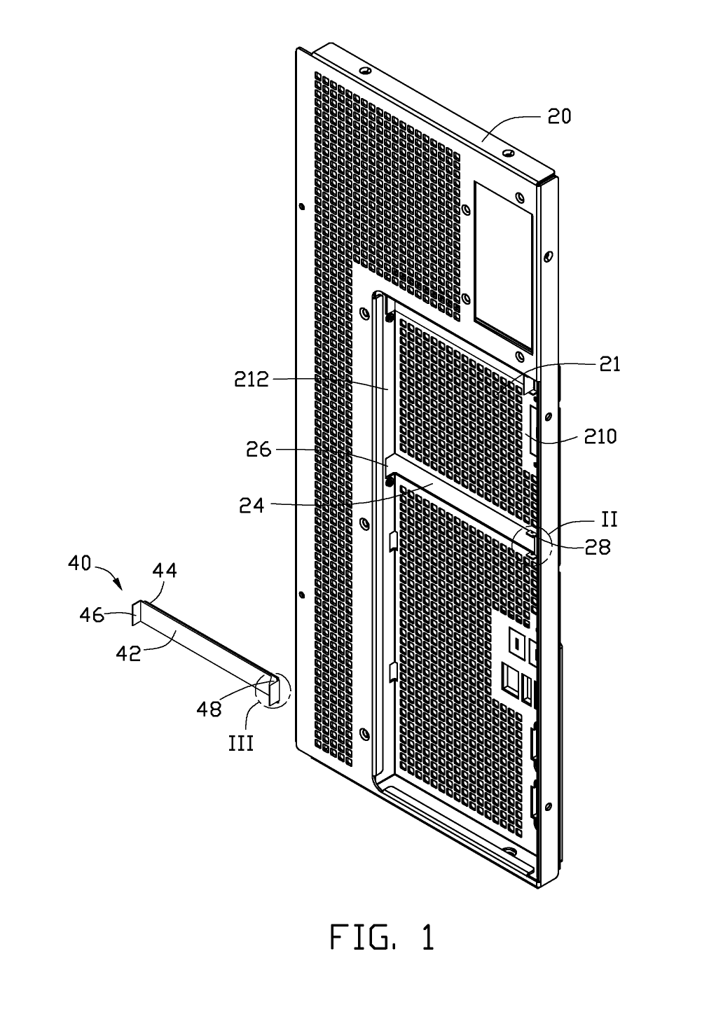

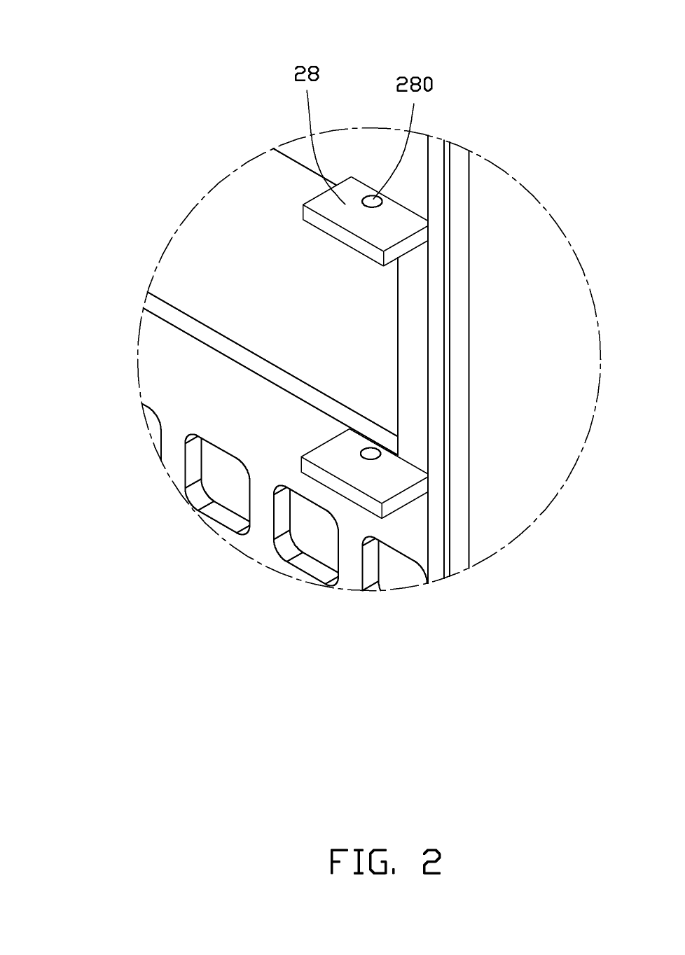

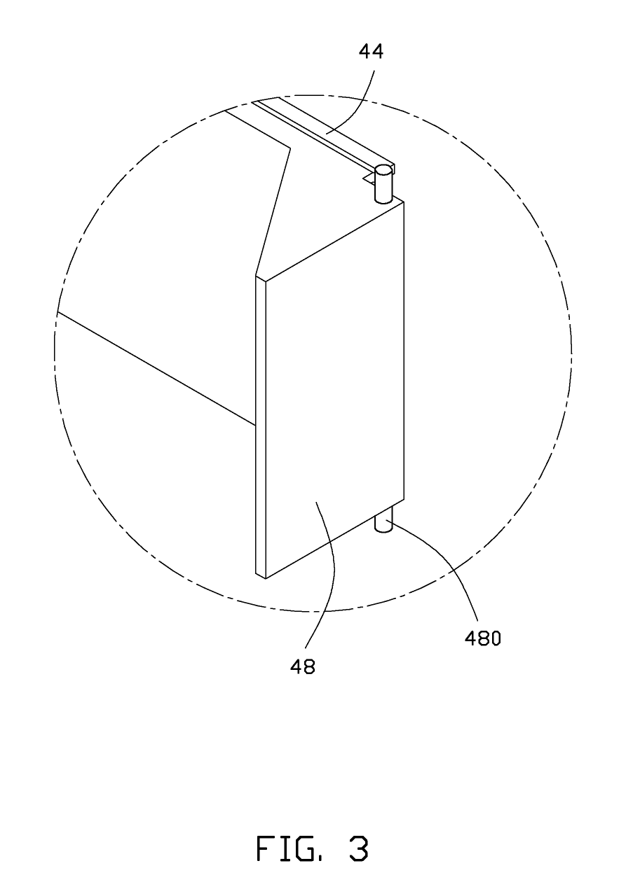

Referring to FIGS. 1 to 3, an exemplary embodiment of a rear wall of an electronic device chassis, such as a computer chassis, includes a wall body 20 and a cover 40.

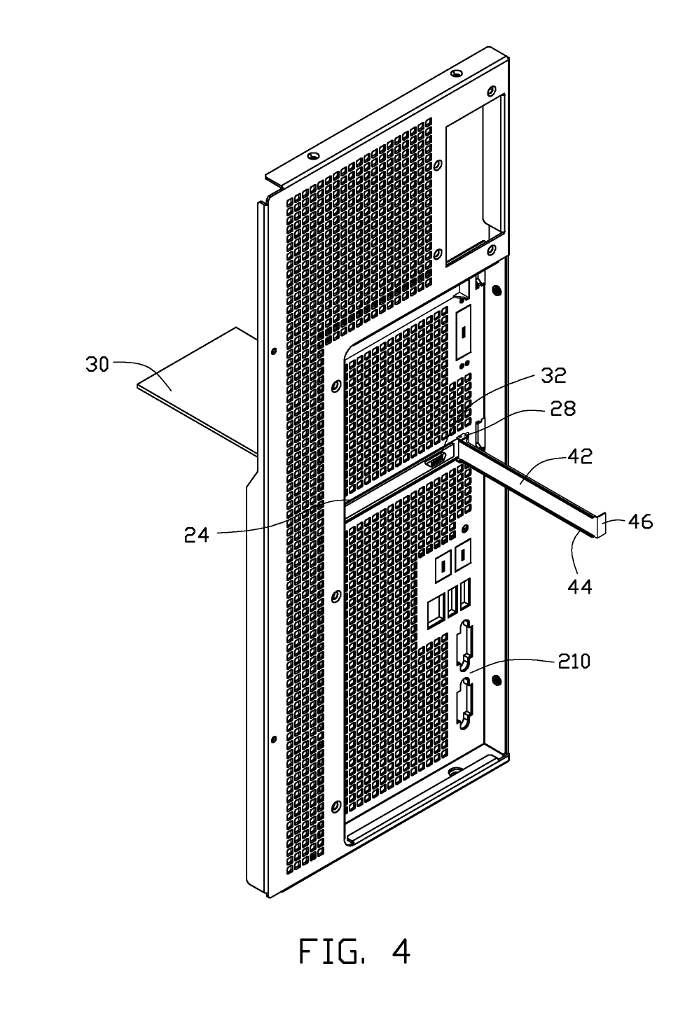

The wall body 20 defines a depressed portion 21 in an outer surface. The depressed portion 21 includes a bottom wall 210 parallel to the wall body 20, and a sidewall 212 perpendicularly connected between a side of the bottom wall 210 and the wall body 20. The bottom wall 210 defines a slot 24 perpendicular to the sidewall 212, to allow a connector 32 of an expansion card 30 (shown in FIG. 4) to extend through. The sidewall 212 defines an opening 26 communicating with the slot 24. Two tabs 28 extend from an outer surface of the bottom wall 210, and are positioned at opposite sides of an end of the slot 24 opposite to the opening 26. Each tab 28 defines a through hole 280.

The cover 40 includes a plate 42, two resilient pieces 44 perpendicularly extending from top and bottom sides of the plate 42, and a blocking piece 46 and a positioning piece 48 perpendicularly extending from opposite ends of the plate 42 away from the resilient pieces 44. Two pins 480 extend out from top and bottom sides of the positioning piece 48.

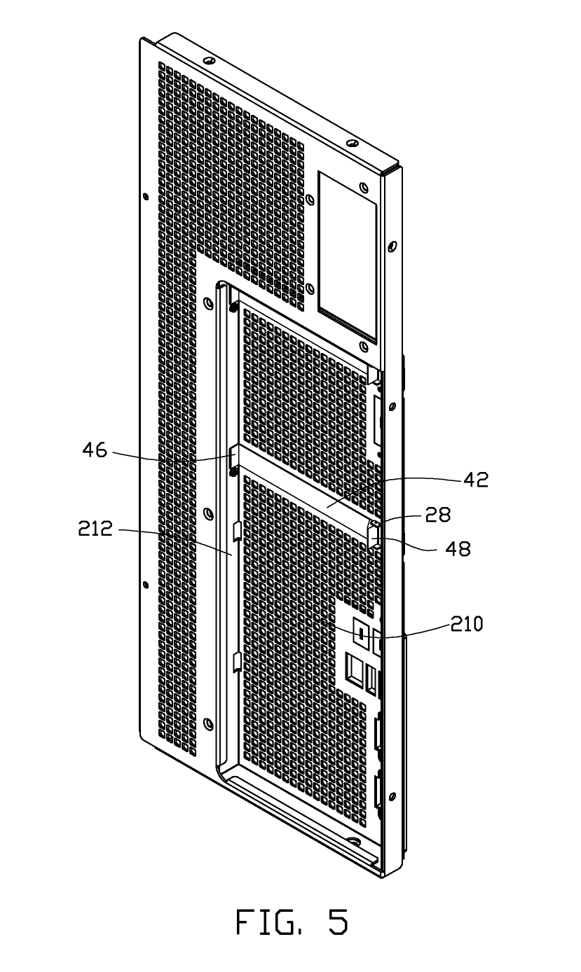

Referring to FIGS. 4 and 5, in assembly, the resilient pieces 44 face the bottom wall 210. The pins 480 are pivotably inserted into the through holes 280, to pivotably mount the cover 40 to the wall body 20.

When the slot 24 needs to be uncovered to accommodate the connector 32, the cover 40 is pivoted out about the pins 480, until the positioning piece 48 abuts against the outer surface of the wall body 20. When the slot 24 needs to be covered, the cover 40 is pivoted toward the wall body 20. The resilient pieces 44 are deformed to be inserted into the slot 24 and abut against opposite sidewalls bounding the slot 24. The blocking piece 46 is engaged in the opening 26. Thereby, the cover 40 is fixed to the wall body 20 and covers the slot 24 and will not be lost when the slot 24 is in use.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. An electronic device rear wall, comprising a wall body defining a slot to accommodate a connector of an expansion card; and a cover pivotably mounted to the wall body to cover or uncover the slot.

2. The rear wall of claim 1, wherein two tabs extend from an outer surface of the wall body and are positioned at opposite sides of an end of the slot, the cover comprises a plate covering the slot, and two pins extending from opposite sides of an end of the plate to be pivotably inserted into the tabs.

3. The rear wall of claim 1, wherein a positioning piece extends from the end of the plate, the pins extend from opposite sides of the positioning piece.

4. The rear wall of claim 2, wherein the wall body defines a depressed portion comprising a bottom wall and a sidewall perpendicularly connected between the wall body and the bottom wall, the slot is defined in the bottom wall, the sidewall defines an opening communicating with the slot, the cover further comprises a blocking piece extending from another end of the plate to engage in the opening.

5. The rear wall of claim 2, wherein two resilient pieces perpendicularly extend from opposite sides of the plate to be deformed and inserted into the slot, the resilient pieces abut against opposite sidewalls bounding the slot.
